(19) United States
(12) Patent Application Publication
(10) Pub. No.: US 2011/0057216 A1
(43) Pub. Date: Mar. 10, 2011

(54) Low profile optoelectronic device package

(75) Inventors: Ming-Kuen Chiu, Taipei (TW); Chin-Ta Fan, Taipei (TW); Chien-Cheng Wei, Taipei (TW); Paul Panaccione, Billerica, MA (US)

(73) Assignee: TONG HSING ELECTRIC INDUSTRIES LTD.

(21) Appl. No.: 12/584,779

(22) Filed: Sep. 10, 2009

(51) Int. Cl. H01L 33/00; H01L 31/0232

(52) U.S. Cl. 257/98; 257/432; 257/433; 257/99; 257/E33.058; 257/E31.127

(57) ABSTRACT

A low profile optoelectronic device package has a matalized transparent substrate, a chip and a dam ring. The matalized transparent substrate has a transparent board, a window area, and a metal pattern formed on a face of the transparent board and around the window area and having at least one outer contact pad and at least two contact pads. An active face of the chip is mounted to the at least two inner contact pads and aligned to the window area. A bottom face of the chip, that is opposite to the active face is further added a soldering layer. The dam ring is sealed a joint between the chip and the matalized transparent substrate so as to define an air cavity among the chip, the matalized transparent substrate and the dam ring. The matalized transparent substrate is used as a substrate and an optical cover of a conventional device package, so the optoelectronic device package provides low profile, small area outline, low fabricating cost and high lighting efficiency.

### BACKGROUND OF THE INVENTION

1. Field of the Invention

The present invention is related to an optoelectronic device package, and more particularly a low profile optoelectronic device package.

2. Description of the Related Art

In general, the optoelectronic device includes electrical-to-optical devices or optical-to-electrical sensors. For example, a light emitting diode (hereinafter LED) is one kind of the electrical-to-optical devices. The optical-to-electrical sensors includes photo-diodes, image sensors (CCD, COMS etc.), color sensors, multi-spectral (IR, UV, gamma ray, X-ray . . . etc.) sensors, fiber-optic data sensors, photovoltaic sensors, solar cells or the like.

With reference to FIG. 7, using a conventional high power optoelectronic device package (5) as an example to describe a detailed structure of the optoelectronic device package. The high power optoelectronic device package (5) has a substrate (not numbered), a chip (54) and a transparent encapsulation (55).

The substrate has a hollow casing (51), a heat conductive seat (52), a leadframe (53) and a chip cup (521). The leadframe (53) is formed on the hollow casing (51). The heat conductive seat (52) is mounted inside the hollow casing (51) and separated from the leadframe (53). A bottom face of the heat conductive seat (52) is flushed with that of the hollow casing (51). Therefore, the bottom face of the heat conductive seat (52) is exposed to the bottom face of the hollow casing (52). The chip cup (521) is defined on a top face of the heat conductive seat (52). The chip (54) is mounted inside the chip cup (51) and then wire-bonded to the leadframe (53). An active face faces upwardly. The transparent encapsulation (55) covers to the hollow casing (51) to seal the chip (55), wires (56) and parts of the leadframe (53) inside the hollow casing (51).

The high power optoelectronic device package (5) is mounted on a board (40) of a heat sink, and a thermal conductive pad (41) such as a solder is interposed between the bottom face of the heat conductive seat (52) and the board (40). Therefore, the board (40) is also used to facilitate the heat conduction between them.

With reference to FIGS. 8 and 9, another conventional high power optoelectronic device package (60) has a substrate, a chip (65) and an optical cover (60).

The substrate has a hollow seat (61), an electric conductive base (62) and two soldering electrodes (63, 64). The electric conductive base (62) is mounted inside the hollow seat (61). A bottom face of the electric conductive base (62) is exposed to a bottom face of the hollow seat (61). A part of a top face of the electric conductive base (62) is exposed to a top face of the hollow seat (61) and used as one (63) of the soldering electrodes. The electric conductive base (62) further defines a chip cup (621) on a top face thereof. Therefore, the chip (65) is mounted inside the chip cup (621) and an active face of the chip (65) faces upwardly. A recess (611) is defined to the top face of the hollow casing (61). A bottom of the chip (65) is electronically connected to the electric conductive base (65). The recess (611) further receives the other soldering electrode (64).

The optical cover (66) covers to the substrate by a sealant (661) and has a board (662), a metal line (67) formed a bottom of the board (662), and a center lens (663) upwardly protruded from a top of the board (662). The center lens (663) is aligned to the chip (65) and one end of the metal line (67) is electronically connected to a top of the chip (65) through a solder bump. The other end of the metal line (67) is electronically connected to one of the two soldering electrodes inside the recess (611).

According to above conventional high power optoelectronic device packages, the transparent lens or encapsulation is required to allow light emitting outside of the substrate. Therefore, a thickness of such structure of the conventional high power optoelectronic device package is not easily decreased. Other optoelectronic device package has the same drawback. However, for some light and thin illumination applications, such conventional package of the optoelectronic device is not proper. In addition, some optoelectronic devices, such as the LED device, easily generate large heat, so how to keep the chip in a normal temperature range is important. However, the above chip thermal contact to the board of the heat sink through the heat conductive board or electric conductive set, thermal conducting efficiency is not good.

To overcome the shortcomings, the present invention provides a low profile high power optoelectronic device package to mitigate or obviate the aforementioned problems.

### SUMMARY OF THE INVENTION

An objective of the present invention is to provide a low profile optoelectronic device package that is thin and has a high electrical-to-optical or optical-to-electrical efficiency and a simple package structure to decrease fabricating cost.

The lower profile optoelectronic device package has a matalized transparent substrate, a chip and a dam ring. The matalized transparent substrate has a transparent board, a window area, and a metal pattern formed on a face of the transparent board and around the window area and having at least one outer contact pad and at least two contact pads. An active face of the chip is mounted to the at least two inner contact pads and aligned to the window area. A bottom face of the chip, that is opposite to the active face is further added a soldering layer. The dam ring is sealed a joint between the chip and the matalized transparent substrate so as to define an air cavity among the chip, the matalized transparent substrate and the dam ring. The matalized transparent substrate is used as a substrate and an optical cover of a conventional device package, so the optoelectronic device package provides low profile, small area outline, low fabricating cost and high efficiency.

A second objective of the present invention is to provide a good reliability of the low profile optoelectronic device package. The above air cavity is full of an optical encapsulation to increase a connecting strength between the chip and the matalized transparent substrate.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a first embodiment of an optoelectronic device package in accordance with the present invention;

FIG. 2A is a side plan view of FIG. 1;

FIG. 2B is a side plan view of a second embodiment of an optoelectronic device package in accordance with the present invention;

FIG. 3 is a top plan view of a metalized transparent board in accordance with the present invention;

FIG. 4 is a side plan view of the optoelectronic device package mounted on a printed circuit board in accordance with the present invention;

FIG. 5 is a side plan view of a third embodiment of an optoelectronic device package in accordance with the present invention;

FIG. 6A is a top plan view of a metalized glass for fabricating the optoelectronic device packages in accordance with the present invention;

FIG. 6B is a rear plan view of the metalized transparent board for fabricating the optoelectronic packages in accordance with the present invention;

FIG. 7 is a cross sectional view of a first conventional high power optoelectronic package mounted on a printed circuit board in accordance with the prior art;

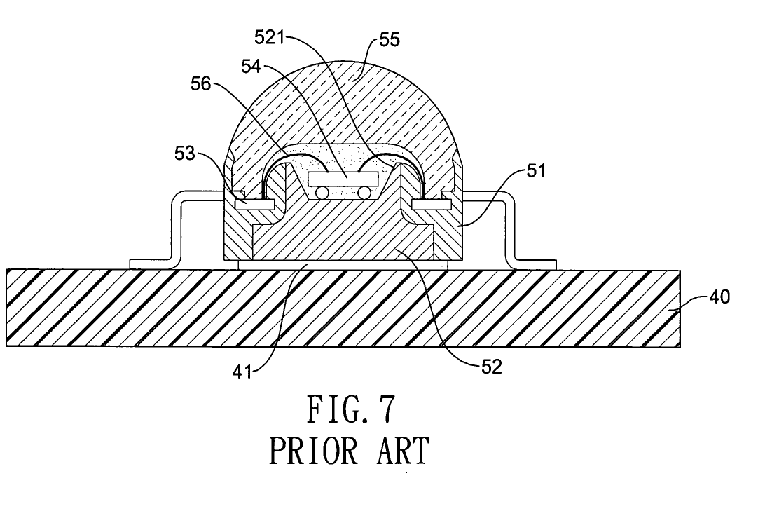

FIG. 8 is a cross sectional view of a second conventional high power optoelectronic package mounted on a printed circuit board in accordance with the prior art; and

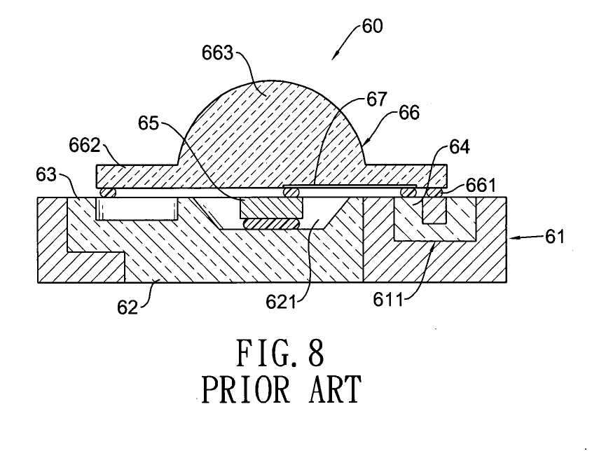

FIG. 9 is a perspective cross sectional view of FIG. 8.

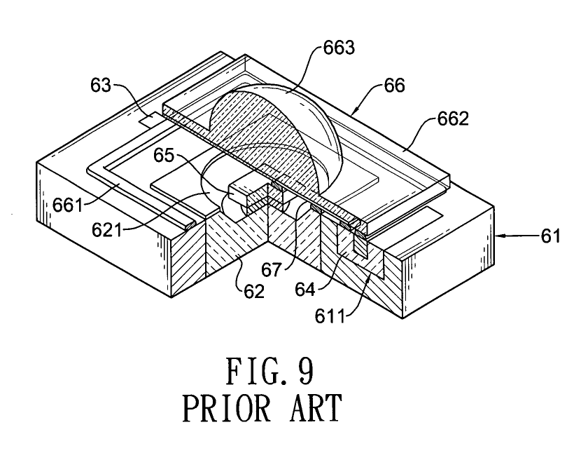

### DETAILED DESCRIPTION OF THE INVENTION

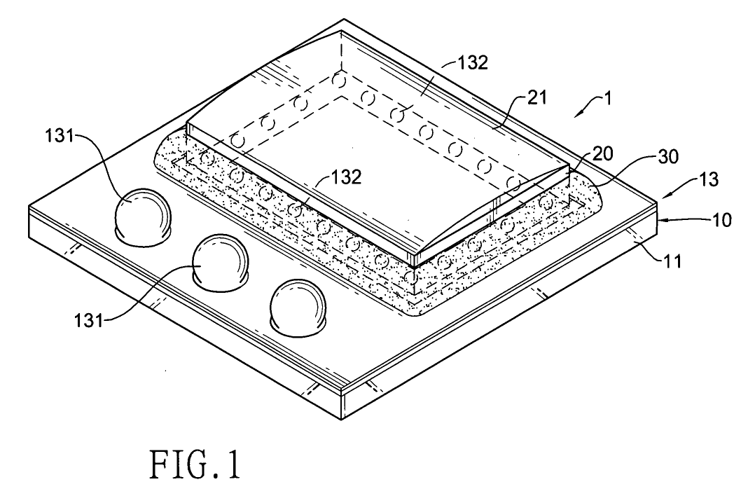

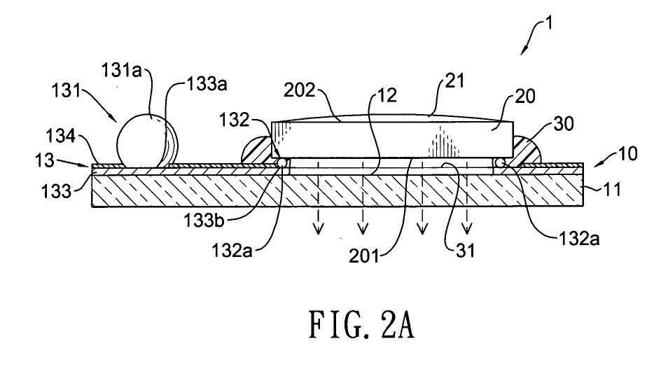

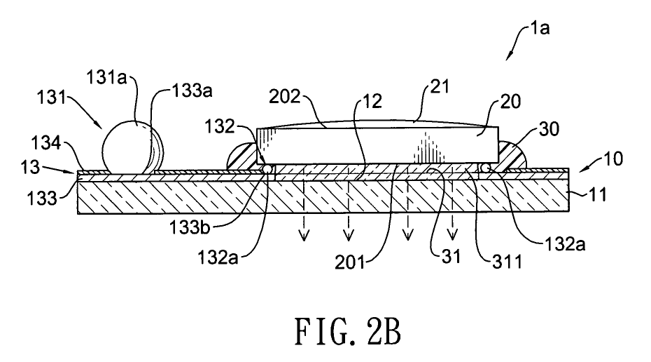

With reference to FIGS. 1 and 2A, a first embodiment of an optoelectronic device package (1) has a matalized transparent substrate (10), a chip (20) and a dam ring (30).

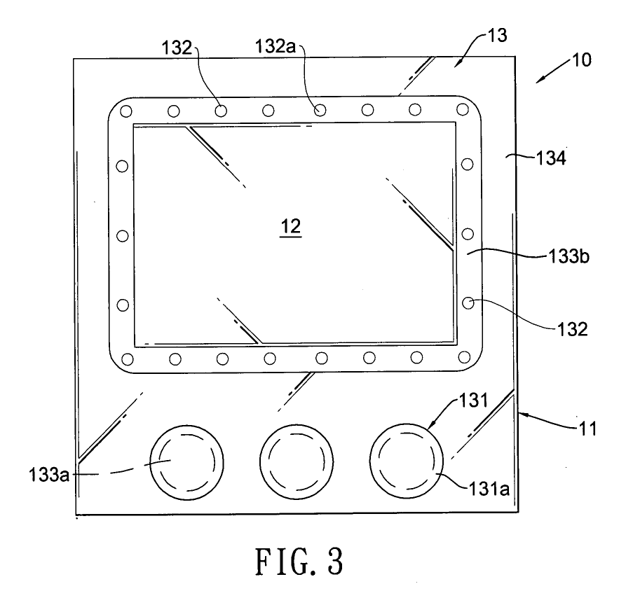

With further reference to FIG. 3, the matalized transparent substrate (10) has a transparent board (11), a window area (12) and a metal pattern (13). The transparent board (11) has two opposite faces. The metal pattern (13) is formed around edges of one face of the transparent board (13) to define the window area (12) on the transparent board (11). The metal pattern (13) has at least two inner contact pads (132) and at least one outer contact (131) electronically connected to the least two inner contact pads (132). The least two inner contact pads (132) are respectively adjacent to two opposite sides of the window area (12) and the least one outer contact pad (131) is separated from at least two the inner contact pads (132). In a preferred embodiment, the metal pattern (13) has a metal layer (133), an insulating layer (134), at least one first stud (131a) and at least two second studs (132b). The metal layer (13) is formed on one of the two opposite face of the transparent board (11). The insulating layer (134) is coated on the metal layer (133) partially and at least three parts of the metal layer (133) corresponding to positions of the at least one outer contact (131) and the at least two inner contacts (132) are exposed. One exposed part (133a) of the metal layer (133) corresponding to the outer contact pad (131) is connected to the first stud (131a), so the first stud (131a) is used as the outer contact pad (131). Others exposed parts (133b) of the metal layer (133) corresponding to the inner contact pads (132) are respectively connected to the second studs (132a), so the second studs (132a) are used as the inner contact pads (132). The first and second studs may be Au, conductive polymer, Cu, etc studs, or solder bumps, or the like.

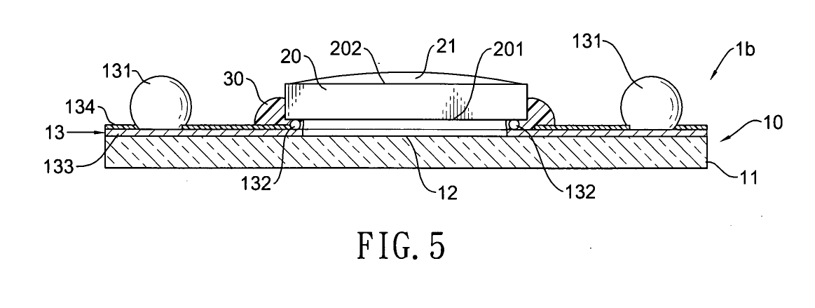

In the first embodiment, the transparent board (11) is a glass board. The matalized transparent board (10) has three outer contact pads (131) formed on one side of the face of the transparent board (11). With further reference to FIG. 5, a second embodiment of a low profile optoelectronic device package (1b), the outer contact pads (131) are respectively to two opposite sides of the face of the substrate board (11) or four sides thereof. Therefore, either the first embodiment or the second embodiment of the optoelectronic device package is a surface mounted package.

The chip (20) has an active face (201) and an electrode face (202) being opposite to the active face (201). The active face (201) is facing downwardly, aligned to the window area (12) of the matalized transparent substrate (10) and connected to the at least two inner contact pads (132). The electrode face (202) is facing upwardly and a soldering layer (21) is directly formed on the electrode face (202). A height of the soldering layer (21) on the electrode face (202) of the chip (20) is equal to that of the at least one outer contact pad (131). In the preferred embodiment, the chip (20) may be LED chip and constructed from III-V semiconductors such as AlGaAs, InGaAs or GaN. The active face of the LED chip is a light emitting face. In other preferred embodiment, the chip may be an optical-to-electrical chip and the active face thereof is a light sensing face. The optical-to-electrical chip may be photo-diode chip, image sensor chip (CCD, COMS etc.), color sensor chip, multi-spectral (IR, UV, gamma ray, X-ray . . . etc.) sensor chip, fiber-optic data sensor chip, photovoltaic sensor chip, solar cell chip or the like.

The dam ring (30) is formed around a joint between the chip (20) and the matalized transparent substrate (10) to seal the inner contact pads (132) and the window area (12). Therefore, an air cavity (31) is defined among the active face (201) of the chip (22), the matalized transparent substrate (10) and the dam ring (30). Since the dam ring (30) may be made of silicon, the dam ring (30) enhances an adhesion between chip (20) and the matalized transparent substrate (10), prevents lights of the chip (20) from radiating to a gap between the chip (20) and the matalized transparent substrate (10), and also prevents environment lights from radiating into the window area (12) of the matalized transparent substrate (10).

With reference to FIG. 2B, a second embodiment of an optoelectronic device package is similar to the first embodiment thereof. In the second embodiment, the air cavity is further full of an optical encapsulation (311) to increase a connecting strength between the chip and the matalized transparent substrate (10).

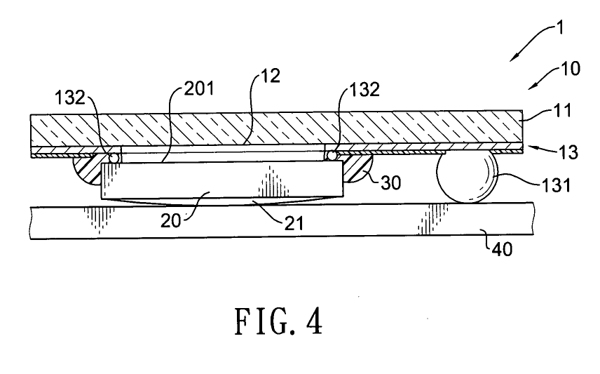

With reference to FIG. 4, the first embodiment of the optoelectronic device package (1) in accordance with the present invention is revised and then soldered to a board (40) of a heat sink by a standard solder reflow assembly procedure. Therefore, the chip (20) directly thermal conducts to the board (40) of the heat sink to increase a heat dissipating efficiency of the optoelectronic device package (1). Accordingly, the optoelectronic device package (1) provides a high lighting efficiency.

Based on the foregoing description, the optoelectronic device package (1) uses the matalized transparent substrate (10) and the active face (201) of the chip (20) faces to the window area (12) of the matalized transparent substrate (10), an external optical cover or transparent encapsulation is not required. That is, the matalized transparent substrate (10) has functions of the substrate and optical covers of the conventional optoelectronic device package. Since the optoelectronic device package (1, 1a, 1b) does not use an external optical cover or transparent encapsulation to seal the chip inside the substrate, the optoelectronic device package (1, 1a) has thin profile and small area outline, and provides a simple package structure to decreasing fabricating cost. In addition, the chip of the present invention is not wire bound to the substrate, the active face of the chip is not blocked by the wires and the electrical-to-optical or optical-to-electrical efficiency is increased. Further, for some applications using optical-to-electrical sensors, the active face of the chip of the present invention is as close as possible to a light emitting source.

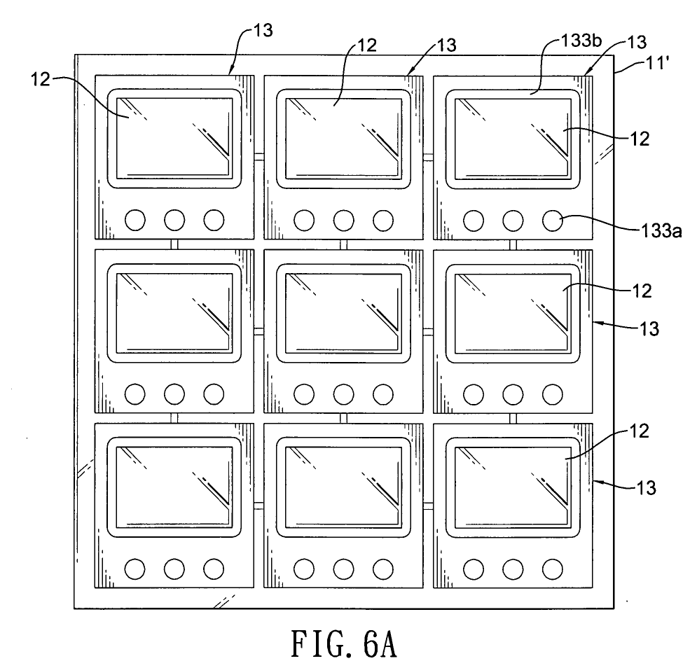

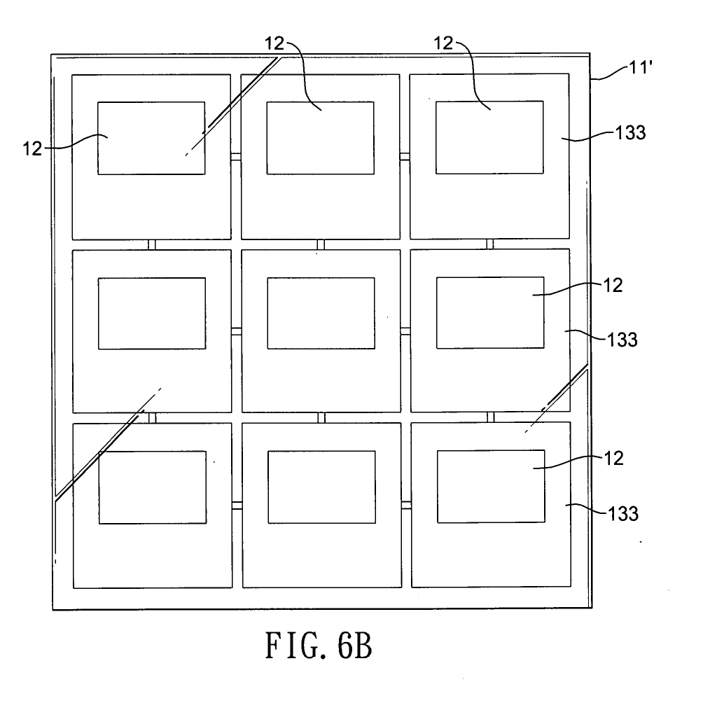

With reference to FIGS. 6A and 6B, a matalized glass board (11′) is used to package great quantity of the chips. In a preferred embodiment, a top face of the matalized glass has 3×3 substrate units, each of which has a window area (12) and a metal patters (13) around the corresponding window area (12). That is, the metal patterns (13) are formed on the top face of the glass board (11′) in matrix. When multiple chips have been respectively packaged on the substrate units, multiple substrate units with chip are divided to individual optoelectronic device package.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An optoelectronic device package comprising:
a matalized transparent substrate having:
a transparent board having a first face, a second being opposite to the first face and a window area; and
a metal pattern formed on the first face of the transparent board, around the window area, and having at least one outer contact pad and at least inner contact pads, wherein the at least two inner contact pads are separating to the outer contact pad, electronically connected to the at least one outer contact pad, wherein the least one outer contact pad, and adjacent to the window area;
a chip mounted on the matalized transparent substrate through the at least two inner contact pads and having:
an active face aligned to the window area and mounted to the least two inner contact pad on the first face of the transparent board;
an electrode face being opposite to the active face; and
a soldering layer formed on the electrode face; and
a dam ring formed around a joint between the chip and the matalized transparent substrate to seal the at least two inner contact pads and the window area so as to define an air cavity among the active face of the chip, the matalized transparent substrate and the dam ring.

2. The optoelectronic device package as claimed in claim 1, wherein the active face is a light emitting face.

3. The optoelectronic device package as claimed in claim 1, wherein the active face is a light sensing face.

4. The optoelectronic device package as claimed in claim 2, wherein the air cavity is further full of an optical encapsulation.

5. The optoelectronic device package as claimed in claim 3, wherein the air cavity is further full of an optical encapsulation.

6. The optoelectronic device package as claimed in claim 2, wherein the least two inner contact pads are respectively adjacent to two opposite sides of the window area.

7. The optoelectronic device package as claimed in claim 4, wherein the least two inner contact pads are respectively adjacent to two opposite sides of the window area.

8. The optoelectronic device package as claimed in claim 3, wherein the least two inner contact pads are respectively adjacent to two opposite sides of the window area.

9. The optoelectronic device package as claimed in claim 5, wherein the least two inner contact pads are respectively adjacent to two opposite sides of the window area.

10. The optoelectronic device package as claimed in claim 2, wherein the metal pattern comprises:
a metal layer formed on the first second of the transparent board;
an insulating layer coated on the metal layer partially and at least three parts of the metal layer corresponding to positions of the at least one outer contact and the at least two inner contacts exposed;
at least one first stud mounted to the at least one exposed part of the metal layer corresponding to the at least one outer contact pad to use as the at least one outer contact pad; and
at least two second studs respectively mounted to the at least two exposed parts of the metal corresponding to the inner contact pads to use as the at least two inner contact pads.

11. The optoelectronic device package as claimed in claim 3, wherein the metal pattern comprises:
a metal layer formed on the first second of the transparent board;
an insulating layer coated on the metal layer partially and at least three parts of the metal layer corresponding to positions of the at least one outer contact and the at least two inner contacts exposed;
at least one first stud mounted to the at least one exposed part of the metal layer corresponding to the at least one outer contact pad to use as the at least one outer contact pad; and
at least two second studs respectively mounted to the at least two exposed parts of the metal corresponding to the inner contact pads to use as the at least two inner contact pads.

12. The optoelectronic device package as claimed in claim 4, wherein the metal pattern comprises:
a metal layer formed on the first second of the transparent board;
an insulating layer coated on the metal layer partially and at least three parts of the metal layer corresponding to positions of the at least one outer contact and the at least two inner contacts exposed;
at least one first stud mounted to the at least one exposed part of the metal layer corresponding to the at least one outer contact pad to use as the at least one outer contact pad; and
at least two second studs respectively mounted to the at least two exposed parts of the metal corresponding to the inner contact pads to use as the at least two inner contact pads.

13. The optoelectronic device package as claimed in claim 5, wherein the metal pattern comprises:
a metal layer formed on the first second of the transparent board;
an insulating layer coated on the metal layer partially and at least three parts of the metal layer corresponding to positions of the at least one outer contact and the at least two inner contacts exposed;
at least one first stud mounted to the at least one exposed part of the metal layer corresponding to the at least one outer contact pad to use as the at least one outer contact pad; and
at least two second studs respectively mounted to the at least two exposed parts of the metal corresponding to the inner contact pads to use as the at least two inner contact pads.

14. The optoelectronic device package as claimed in claim 10, wherein each of the at least one first and the at least two second studs is solder bump or made of Au, Cu or conductive polymer.

15. The optoelectronic device package as claimed in claim 11, wherein each of the at least one first and the at least two second studs is solder bump or made of Au, Cu or conductive polymer.

16. The optoelectronic device package as claimed in claim 12, wherein each of the at least one first and the at least two second studs is solder bump or made of Au, Cu or conductive polymer.

17. The optoelectronic device package as claimed in claim 13, wherein each of the at least one first and the at least two second studs is solder bump or made of Au, Cu or conductive polymer.

18. The optoelectronic device package as claimed in claim 2, wherein the dam ring is made of silicon and the transparent board is a glass board.

19. The optoelectronic device package as claimed in claim 3, wherein the dam ring is made of silicon and the transparent board is a glass board.

20. The optoelectronic device package as claimed in claim 1, wherein a height of the soldering layer on the electrode face of the chip is equal to that of the at least one outer contact pad.
